(19) United States
(12) Patent Application Publication
(10) Pub. No.: US 2026/0032806 A1
(43) Pub. Date: Jan. 29, 2026

(54) CROSSTALK CANCELLATION

(71) Applicant: Micron Technology, Inc., Boise, ID (US)

(72) Inventors: Carlos Jesus Franco Tinoco, Boise, ID (US); Dan Soto, Boise, ID (US)

(21) Appl. No.: 18/787,918

(22) Filed: Jul. 29, 2024

(51) Int. Cl. H05K 1/02; H05K 1/11; H05K 1/18

(52) U.S. Cl. CPC H05K 1/0228; H05K 1/115; H05K 1/181; H05K 2201/10159

(57) ABSTRACT

Signal lines within an electronic system can be aligned in a spiral pattern. Additionally, two adjacent signal lines, with at least one of the signal lines aligned in a spiral pattern, can be arranged in a particular manner, in which signals on the two signal lines are transmitted in opposite directions. Some of the spiral patterns formed within the electronic system can be intertwined with one another.

### TECHNICAL FIELD

Embodiments of the disclosure relate generally to electronic systems, and more specifically, relate to crosstalk cancellation.

### BACKGROUND

Electronic devices, such specialized circuits like Application-Specific Integrated Circuits (ASICs), memory devices, memory packages, include and utilize a number of signal lines, which can be unidirectional or bidirectional, for transmitting signals among various locations of the electronic devices.

### BRIEF DESCRIPTION OF THE DRAWINGS

The present disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example electronic system including signal lines that are aligned in a particular pattern in accordance with some embodiments of the present disclosure.

FIGS. 2A-1 and 2A-2 illustrate both three-dimensional and top views of example alignment of signal lines coupled between various nodes in accordance with some embodiments of the present disclosure.

FIGS. 2B-1 and 2B-2 illustrate both three-dimensional and top views of another example alignment of signal lines coupled between various nodes in accordance with some embodiments of the present disclosure.

FIGS. 2C-1 and 2C-2 illustrate both three-dimensional and top views of another example alignment of signal lines coupled between various nodes in accordance with some embodiments of the present disclosure.

FIG. 3 illustrates a top view of example alignment of signal lines positioned adjacent to one another in accordance with some embodiments of the present disclosure.

FIG. 4 illustrates a top view of another example alignment of signal lines positioned adjacent to one another in accordance with some embodiments of the present disclosure.

FIGS. 5A and 5B respectively illustrate three-dimensional and top views of example alignment of signal lines positioned adjacent to one another in accordance with some embodiments of the present disclosure.

FIGS. 6A and 6B illustrate a top view of example alignment of signal lines positioned adjacent to one another in accordance with some embodiments of the present disclosure.

### DETAILED DESCRIPTION

Aspects of the present disclosure are directed to crosstalk cancellation. Crosstalk is an undesirable phenomenon that can occur in data buses and other communication lines, especially when multiple signals are present in close proximity to each other. For example, when a signal is transmitted on one wire, this can induce an undesired signal in an adjacent wire, causing interference. Crosstalk can occur in various forms, such as in Near-End Crosstalk (NEXT), Far-End Crosstalk (FEXT), Alien Crosstalk, etc. NEXT occurs when the transmitted signal on one wire induces an unwanted signal on an adjacent wire close to the transmitting end. NEXT is measured at or near the source (e.g., transmitting end) of the transmitting signal. FEXT occurs when the transmitted signal on one wire induces an unwanted signal on an adjacent wire far from the transmitting end. FEXT is measured at the receiving end of the transmitted signal.

In electronic systems, such as memory systems, the presence of multiple channel components (e.g., signal lines formed of wires), necessitates various design consideration, as the performance of the entire system can be significantly degraded if any one of the channel components experiences crosstalk-related bottlenecks. The crosstalk-related bottlenecks refers to situations in which crosstalk becomes a limiting factor for the performance of the systems. For example, in data transmission systems, such as Solid-State Drive (SSD) systems, the crosstalk on one or more channel components that surpass acceptable limits can result in data corruption, reduced read/write speeds, or even system instability. Therefore, optimizing various components within electronic systems without addressing the crosstalk issue may result in significant inefficiency for the efforts of enhancing overall system performance.

Aspects of the present disclosure address the above and other deficiencies by providing signal wire alignment in particular patterns (e.g., coil patterns), which can provide crosstalk cancellation; thereby, allowing the system performance to be optimized without the crosstalk issues being a point of failure for the optimization. The signal wire alignment according to the embodiments of the present disclosure is directed to cancelling FEXT crosstalk by controlling mutual inductance. For example, consider the following equation for calculating FEXT crosstalk.

$$f ( x ) = {a}_{0} + {\sum }_{n = 1}^{∞} ( {a}_{n} cos \frac{n π x}{L} + {b}_{n} sin \frac{n π x}{L} ) FEXT = ( \frac{{V}_{FE}}{{V}_{A}} ) = \frac{1}{2} * ( \frac{length}{( vel * trise )} ) * ( \frac{{C}_{M}}{{C}_{L}} - \frac{{L}_{M}}{{L}_{L}} ) \qquad Equation ( 1 )$$

In equation (1), V_{FE} is voltage level at the far end, V_{A} is an aggressor's voltage level, “length” refers to a length of the cable (e.g., signal line), “vel” refers to a velocity, “trise” refers to a rise time, “M” subscript refers to the mutual inductance/capacitance, and the “L” subscript refers to the victim line's inherent inductance/capacitance.

As shown in the equation, if the relative conductive (e.g., C_{M}/C_{L}) and inductive (e.g., L_{M}/L_{M}) contributions (e.g., behaviors) to FEXT are equal, then they cancel each other, which would minimize and/or make FEXT to zero (e.g., “0”). While the mutual capacitance (e.g., C_{M}) can be adjusted (e.g., increasing) to minimize and/or make FEXT to zero (e.g., “0”), the increased mutual capacitance can lead to undesirable effects, such as insertion loss (IL), intersymbol interference (ISI), etc. Therefore, embodiments of the present disclosure can provide adjusting (e.g., controlling) mutual inductance (instead of the mutual capacitance) to make the relative inductive behavior equal to the relative conductive behavior, which can still minimize FEXT to zero. This avoids the undesirable effects resulting from adjusting (e.g., increasing) the mutual capacitance).

In a number of embodiments, adjusting the relative inductance can be achieved by aligning one or more signal lines (positioned adjacent to one another) in a spiral pattern (e.g., a coil pattern) at one or both (e.g., transmitting and/or receiving) ends. Further, the signal lines can be aligned in a particular manner such that signals transmitted over the signal lines are in opposite directions to one another. For example, while a first signal line aligned in a spiral manner can carry a signal in a clockwise direction, a second signal line also aligned in a spiral manner and adjacent to the first signal line can carry a signal in a counter-clockwise direction. The signals transmitted in opposite directions can intentionally create “inverted inductive coupling” (alternatively referred to as “negative inductive coupling” and simply referred to as “inverted coupling”) along the signal path that have been primarily affected by “dominant inductive coupling”. As used herein, the term “dominant inductive coupling” refers to the phenomenon in which electromagnetic interference (EMI) is primarily caused by inductive coupling between two or more electronic circuits. This intentionally-introduced inverted coupling can control (e.g., reduce) the mutual inductance between the adjacent signal lines, which further reduce/minimize the crosstalk in a “victim” region, such as a far-end of signal lines. This combination of the spiral pattern and signal directions as described above can address the crosstalk issues in either end of the signal transmission without compromising the system's ISI performance, such as system's ability to accurately decode symbols, thus maintaining overall signal integrity.

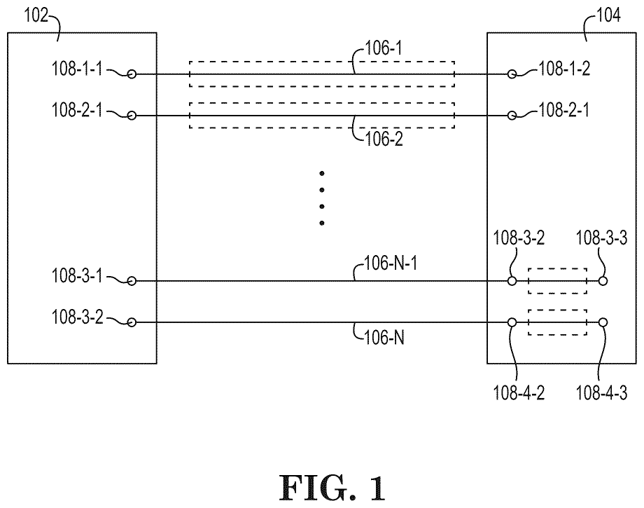

FIG. 1 illustrates an example electronic system 100 including signal lines 106-1, . . . , 106-N that are aligned in a particular pattern in accordance with some embodiments of the present disclosure. The electronic system 100 can be, or can be part of, for example, a desktop computer, laptop computer, televisions, home theater system, gaming console, digital camera, network router and/or switch, printer, scanner, medical device, GPS navigation device, home device (e.g., thermostat, doorbell camera, security camera, smart lock, etc.), wearable device, industrial control system (e.g., automated industrial and/or control device) mobile computing device, a vehicle (e.g., airplane, drone, train, automobile, or other conveyance), Internet of Things (IoT) enabled device, embedded computer (e.g., one included in a vehicle, industrial equipment, or a networked commercial device), system-on-chip (SoC), chipset (e.g., a collection of integrated circuits), tile, Field-Programmable Gate Array (FPGA) structure (e.g., segmented FPGA structure), or other such device. Although embodiments are not so limited, in some embodiments, the electronic system 100 can be a controller package, such as Application-Specific Integrated Circuit (ASIC) package (e.g., 6-layer package, 8-layer package, etc.). In this example,

As illustrated in FIG. 1, the electronic system 100 includes two components 102 and 104. However, embodiments are not limited to a particular quantity of components the electronic system 100 can include. For example, the component 102 can be coupled to more than one component 104, while the component 104 can also be coupled to more than one component 102.

Although embodiments are not so limited, components can be constituent entities of the electronic system 100 that can communicate (e.g., transmit, receive, etc.) signals with the other components via signal lines 106-1, . . . , 106-N. Examples of components can include, but not limited to, a controller, a memory mediums and/or modules, one or different layers of the controller package (e.g., ASIC package), various communication mediums within the layers of the controller package, such as a number of vias, ball grid array (BGA) balls, etc.

In some embodiments, the components 102, 104 being memory media can include volatile memory devices, such as (but not limited to) random access memory (RAM), such as dynamic random-access memory (DRAM) and synchronous dynamic random access memory (SDRAM) or nonvolatile memory, such as negative-and (NAND) type flash memory, read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM). The components 102, 104 being memory modules can be Dual Inline Memory Module (DIMM) and/or module that contain multiple memory chips (e.g., DRAM chips). In some embodiments, the component 102 can correspond to a controller package, while the component 104 can correspond to a memory package, although embodiments are not so limited. The components 102 and 104 may be (e.g., mounted) on the same PCB and on different PCBs respectively.

Components (e.g., components 102 and 104) of the electronic system 100 are coupled to each other via signal lines 106-1, . . . , 106-N(collectively referred to as signal lines 106). The signal lines 106 can carry various types of signals, such as data signals (e.g., in forms of digital signals, analog signals, etc.), address signals (e.g., memory address signals, input/output (I/O) signals, etc.), control signals (read/write signals, chip select signals, etc.), power signals (VCC, VDD, GND, etc.), clock signals, although embodiments are not so limited. In some embodiments, each signal line 106 can respectively be a physical connection, such as a physical wire.

In some embodiments, the signal lines 106 can (e.g., at least partially) be single-ended buses, in which data signals are transmitted along a single wire and each data signal is referenced to a single common ground or voltage level. However, embodiments are not so limited. For example, the signal lines 106 can also be differential buses, in which data signals are transmitted along two complementary wires, with the signal being the voltage difference between them.

Signal lines 106 can be aligned in a manner that respectively form various patterns between nodes, such as nodes 108-1-1, 108-1-2, 108-2-1, 108-2-2, . . . , 108-3-1, 108-3-2, 108-4-1, 108-4-2 (collectively referred to as nodes). For example, although not precisely depicted in FIG. 1, the signal lines 106-1 and 106-2 can be aligned to respectively form various patterns (e.g., spiral patterns, rectangular spiral patterns, etc.) between nodes 108-1-1 and 108-1-2 and nodes 108-2-1 and 108-2-2, respectively. Further, for example, although not precisely depicted in FIG. 1, the signal lines 106-N-1 and 106-N can be aligned to respectively form various patterns (e.g., spiral patterns, rectangular spiral patterns, etc.) between nodes 108-3-2 and 108-3-4 and nodes 108-4-2 and 108-4-3, respectively.

As used herein, the term “node” refers to either a connection point via which signal lines (e.g., signal lines 106) are connected/coupled to the other components of the electronic system (e.g., the electronic system 100) or an intermediate point. For example, although embodiments are not so limited, nodes can be soldered joints, connector pins, pads, sockets, headers, solder balls, such as ball grid array (BGA) balls, solder bumps, various metal contacts, etc. via which the signal lines can be connected/coupled to the other components (printed circuit board (PCB), vias, substrate, connectors, semiconductor die, controller package, memory package, memory modules, etc.) of the electronic system. The term “intermediate point” refers to a node that serves as an intermediary in the signal line (but may not be part of the components, such as components 102 and/or 104), either as a part of it or created to extend it, often to modify the alignment pattern of the signal line. For example, nodes 108-3-2 and 108-4-2 can serve as intermediate nodes for the signal lines 106-N-1 and 106-N, respectively. As used herein, a node that serves an intermediate point can be referred to as an “intermediate node”. In some embodiments, the intermediate node may serve as a starting point of a spiral pattern formed by the signal line.

As illustrated in FIG. 1, nodes between which the patterns can be formed according to a number of embodiments of the present disclosure can be respectively located at different components, such as at components 102 and 104, respectively. For example, the patterns respectively formed by the signal lines 106-1 and 106-2 can be between nodes 108-1-1 and 108-1-2 or between nodes 108-2-1 and 108-2-2 that are located on the components 102 and 104, respectively. However, embodiments are not so limited. For example, the patterns respectively formed by the signal lines 106-N-1 and 106-N can be between nodes 108-3-2 and 108-3-3 or between nodes 108-4-2 and 108-4-3 that are located on the component 104, but not on the component 102.

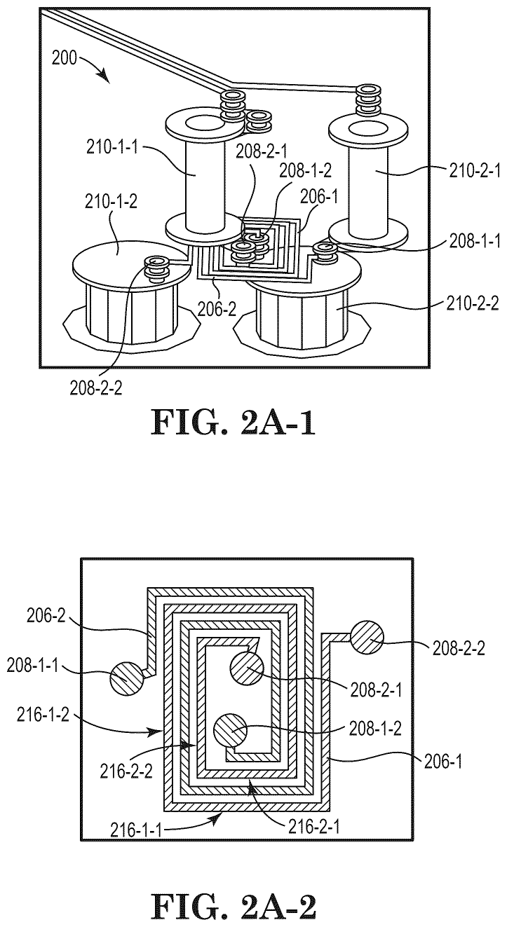

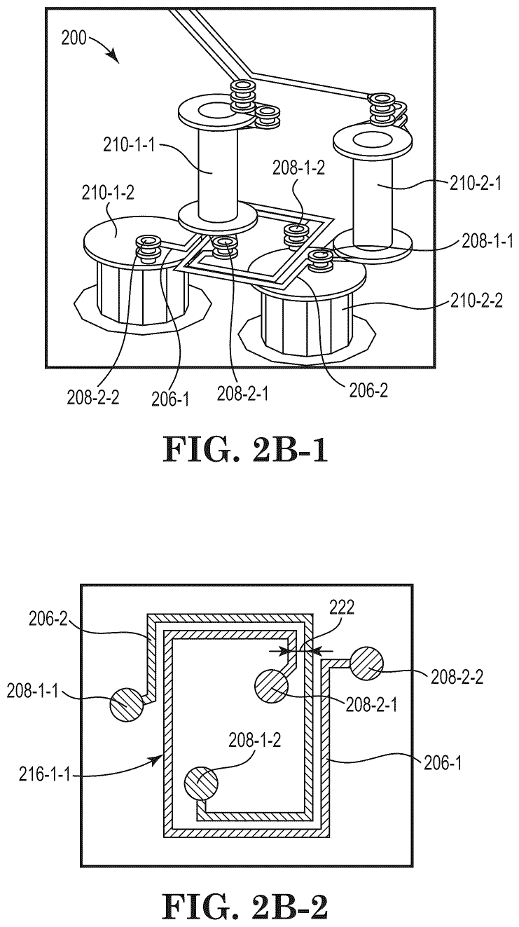

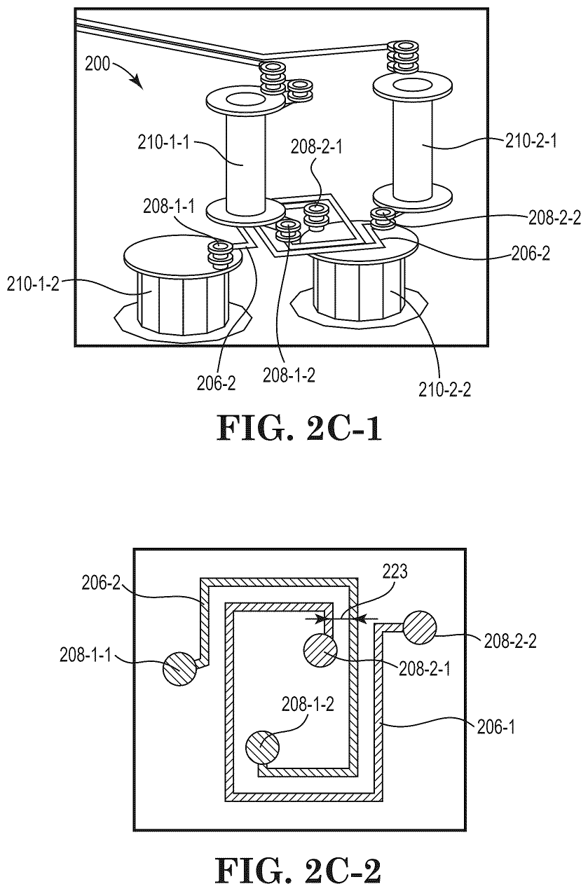

The patterns that can be formed by signal lines 106 can be “spiral” or “coil” patterns. As used herein, the terms “spiral pattern” and “coil pattern” refer to a type of geometric arrangement in which a series of shapes, lines or structures repeats around a central point or axis in a manner that resembles the shape of a spiral. In various embodiments, the shapes in a spiral pattern can progressively diminish (e.g., become smaller) in size as they spiral around the central point or axis. As used herein, the term “rectangular spiral pattern” refers to a spiral pattern in which a series of rectangular shapes repeats and spiral around the central point or axis in a progressively diminishing manner. Further, the term “spiral pattern” can be interchangeably used with the term “spiral shape” and can have the same/substantially same meaning, as appropriate to the context. As further illustrated in FIGS. 2A-2C, 3-4, 5A-5B, and 6A-6B, the spiral pattern/shape can be an “open shape”, which refers to a shape that has distinct endpoints that do not connect to form a complete boundary (thereby, not forming a closed loop), as opposed to a “closed shape”, which refers to a shape in which the constituent endpoints form a continuous and unbroken boundary, allowing the closed shape to have a region. Further details of various manners in which spiral patterns can be formed by signal lines are described below in connection with FIGS. 2A-2C, 3-4, 5A-5B, and 6A-6B.

FIGS. 2A-1 and 2A-2 (collectively referred to as FIGS. 2A) illustrate both three-dimensional and top views of example alignment of signal lines 206-1, 206-2 coupled between various nodes in accordance with some embodiments of the present disclosure. For example, as illustrated in the top view of FIG. 2A-2, the signal line 206-1 is coupled between nodes 208-2-1 and 208-2-2, while the signal line 206-2 is coupled between nodes 208-1-2 and 208-1-1. Alternatively speaking, the nodes 208-2-1 and 208-2-2 are coupled to each other via the signal line 206-1, while the nodes 208-1-2 and 208-1-1 are coupled to each other via the signal line 206-2. The signal lines 206-1, 206-2 can be analogous to the signal lines 106 illustrated in FIG. 1.

The view (e.g., top view) shown in FIGS. 2A-1 (as well as in FIGS. 2B-1, 2C-1, 3, 4, 5A-5B, and 6) provides a two-dimensional representation of the electronic system 200. The view captures the intersection of features of the electronic system 200 as seen from a specific perspective. This specific perspective can be a depiction of a “plane” (e.g., a two-dimensional surface that extends infinitely in all directions, such as in “X” and “Y” axis) that may or may not be at the same height as the signal lines 206 and nodes 208 illustrated in FIGS. 2A-2C, which may exist in a third dimension (e.g., corresponding to “z”-axis) not defined by the plane's two dimensions. For example, while those signal lines 206 and nodes 208 may not be precisely located on the plane shown FIGS. 2A-2C, FIGS. 2A-2C can illustrate the points, lines, and/or patterns on the plane that are obtained as a result of (e.g., resulting from) the projection of the signal lines 206 and nodes 208 onto the plane.

Although embodiments are not so limited, the plane (e.g., imaginary plane) may be in parallel with a particular memory component on which nodes 212 and/or 214 are arranged/formed. For example, the plane may be in parallel with a printed circuit board, a top surface of the controller and/or memory medium/module located on (and in parallel with) the printed circuit board, etc.

Nodes 208-2-1, 208-1-2, 208-2-2, 208-1-1 can be part of components 210-1-1, 210-2-2, 210-1-2, 210-2-1 (collectively referred to as components 210), respectively. The components 210 may be analogous to the components 102, 104 illustrated in FIG. 1. Although embodiments are not so limited, the components 210-1-1, 210-2-1, 210-1-2, 210-2-2 can respectively be vias, BGA balls, etc. of the controller package (e.g., 6-layer ASIC package). More particularly, the components 210-1-1 and 210-2-1 can respectively be a via on one layer of the controller package, while the components 210-1-2 and 210-2-2 can be either vias or BGA balls on another layer or a bottom of the controller package. For example, the components 210-2-1 and/or 210-2-2 can be a BGA of solder balls via which the package (e.g., the controller package, memory package, etc.) can be mounted on the PCB.

Each signal line is aligned in a spiral pattern, such as in a rectangular spiral pattern. For example, both signal lines 206-1 and 206-2 are both aligned in a rectangular spiral pattern that both forms a number of rectangular shapes as illustrated in FIG. 2A-2. In a more particular example, the signal line 206-1 is aligned in a rectangular spiral pattern to form two rectangular shapes (e.g., substantially rectangular shapes): one rectangular shape having line segments 216-1-1 and 216-1-2 that are substantially perpendicular to one another and another rectangular shape having line segments 216-2-1 and 216-2-2 that are substantially perpendicular to one another. As used herein, the term “substantially” means that the characteristic need not be absolute, but is close enough so as to achieve the advantages of the characteristic. For example, “substantially rectangular” is not limited to a shape that is absolutely rectangular and can be a shape that is intended to be rectangular but due to various limitations (e.g., manufacturing limitations) may not be precisely rectangular. In another example, “substantially perpendicular” is not limited to a right angle between two line segments and can be an angle that is intended to be perpendicular but due to various limitations (e.g., manufacturing limitations) may not be precisely perpendicular.

As illustrated in FIG. 2A-1 and 2A-2, two spiral patterns corresponding to the signal lines 206-1, 206-2 are formed in an “intertwined” manner. For example, the two spiral patterns are formed in an “intertwined” manner such that a line segment (not shown in FIG. 2A) drawn between the node 208-2-1 and 208-2-2 intersects the signal line 206-2, while a line segment (not shown in FIG. 2A) drawn between the node 208-1-2 and 208-1-1 intersects the signal line 206-1.

In a number of embodiments, the signal lines 206-1 and 206-2 are formed in an intertwined manner along substantially the same planes (e.g., a two-dimensional surface as mentioned above, such as height or over the z-axis), as also illustrated in FIG. 2A-1. Alternatively speaking, the signal lines 206-1 and 206-2 are substantially adjacent to one another on the respective planes (e.g., height or z-axis). For example, a portion of signal line 206-2 near (or adjacent to) node 208-1-2 is on substantially the same plane (e.g., height) as a portion of signal line 206-1 that is near (or adjacent to) node 208-2-1. Similarly, those portions of signal lines 206-1 and 206-2 are formed substantially on the same plane as they extend respectively toward nodes 208-1-1 and 208-2-2.

The signal lines 206-1, 206-2 can be aligned in a manner that signals on the signal lines 206-1, 206-2 are transmitted in opposite directions. For example, consider an example in which signals are respectively transmitted by the signal lines 206-1, 206-2 from one layer (where the components 210-1-1 and 210-2-1 are located) to another layer (where the components 210-1-2 and 210-2-2 are located). In this example, a signal on the signal line 206-2 is transmitted in a (e.g., clockwise) direction from the “outer” node 208-1-1 (which is the part of the component 210-2-1) to the “inner” node 208-1-2 (which is the part of the component 210-2-2) of the spiral pattern. In contrast, a signal on the signal line 206-1 is transmitted in a (e.g., counter-clockwise) direction from the “inner” node 208-2-1 (which is the part of the component 210-1-1) to the “outer” node 208-1-2 (which is the part of the component 210-1-2) of the spiral pattern. These signals transmitted on adjacent signal lines (e.g., signal lines 206-1, 206-2) in opposite directions can intentionally create inverted inductive coupling, which can cancel and/or mitigate the adverse effects of the crosstalk on the signal lines 206-1, 206-2 (more particularly, on nodes 208-2-2 and 208-1-2, which are respectively a far end of the signal lines 206-1, 206-2.

FIGS. 2B-1 and 2B-2 (collectively referred to as FIG. 2B) illustrate both three-dimensional and top views of another example alignment of signal lines coupled between various nodes in accordance with some embodiments of the present disclosure. The alignment of signal lines 206 shown in FIG. 2B is generally analogous to the alignment of signal lines 206 shown in FIG. 2A. For example, as illustrated in the top view of FIG. 2B, the signal line 206-1 is coupled between nodes 208-2-1 and 208-2-2, while the signal line 206-2 is coupled between nodes 208-1-2 and 208-1-1.

Further, the signal lines 206-1, 206-2 can be aligned in a manner that signals on the signal lines 206-1, 206-2 are transmitted in opposite directions. For example, a signal on the signal line 206-2 can be transmitted in a (e.g., clockwise) direction from the “outer” node 208-1-1 (which is the part of the component 210-2-1) to the “inner” node 208-1-2 (which is the part of the component 210-2-2) of the spiral pattern. In contrast, a signal on the signal line 206-1 can be transmitted in a (e.g., counter-clockwise) direction from the “inner” node 208-2-1 (which is the part of the component 210-1-1) to the “outer” node 208-1-2 (which is the part of the component 210-1-2) of the spiral pattern.

Further, the signal lines 206-1 and 206-2 are formed (e.g., in an intertwined manner) along substantially the same planes (e.g., a two-dimensional surface as mentioned above, such as height or over the z-axis), as also illustrated in FIG. 2B-1. Alternatively speaking, the signal lines 206-1 and 206-2 are substantially adjacent to one another on the respective planes (e.g., height or z-axis). For example, a portion of signal line 206-2 near (or adjacent to) node 208-1-2 is on substantially the same plane (e.g., height) as a portion of signal line 206-1 that is near (or adjacent to) node 208-2-1. Similarly, those portions of signal lines 206-1 and 206-2 are formed substantially on the same plane as they extend respectively toward nodes 208-1-1 and 208-2-2.

However, the signal lines 206 may be aligned in a “less” spiral manner (e.g., having fewer coils). Alternatively speaking, the spiral pattern formed by the signal lines 206-1 and 206-2 of FIG. 2B may include less quantity of shapes than the spiral pattern shown in FIG. 2A. For example, in contrast to the spiral pattern shown in FIG. 2A having at least two rectangular shapes, the spiral pattern shown in FIG. 2B has one rectangular shape (having line segments 216-1-1 and 216-1-2 that are substantially perpendicular to one another). The spiral pattern of FIG. 2B having fewer coils compared to the spiral pattern of FIG. 2A can result in a reduced inductance (e.g., mutual inductance) between the signal lines 206-1 and 206-2.

FIGS. 2C-1 and 2C-2 (collectively referred to as FIG. 2C) illustrate both three-dimensional and top views of another example alignment of signal lines coupled between various nodes in accordance with some embodiments of the present disclosure. The alignment of signal lines 206 shown in FIG. 2C is generally analogous to the alignment of signal lines 206 shown in FIG. 2B. For example, as illustrated in the top view of FIG. 2C, the signal line 206-1 is coupled between nodes 208-2-1 and 208-2-2, while the signal line 206-2 is coupled between nodes 208-1-2 and 208-1-1.

Further, the signal lines 206-1, 206-2 can be aligned in a manner that signals on the signal lines 206-1, 206-2 are transmitted in opposite directions. For example, a signal on the signal line 206-2 can be transmitted in a (e.g., clockwise) direction from the “outer” node 208-1-1 (which is the part of the component 210-2-1) to the “inner” node 208-1-2 (which is the part of the component 210-2-2) of the spiral pattern. In contrast, a signal on the signal line 206-1 can be transmitted in a (e.g., counter-clockwise) direction from the “inner” node 208-2-1 (which is the part of the component 210-1-1) to the “outer” node 208-1-2 (which is the part of the component 210-1-2) of the spiral pattern.

Further, the signal lines 206-1 and 206-2 are formed (e.g., in an intertwined manner) along substantially the same planes (e.g., a two-dimensional surface as mentioned above, such as height or over the z-axis), as also illustrated in FIG. 2C-1. Alternatively speaking, the signal lines 206-1 and 206-2 are substantially adjacent to one another on the respective planes (e.g., height or z-axis). For example, a portion of signal line 206-2 near (or adjacent to) node 208-1-2 is on substantially the same plane (e.g., height) as a portion of signal line 206-1 that is near (or adjacent to) node 208-2-1. Similarly, those portions of signal lines 206-1 and 206-2 are formed substantially on the same plane as they extend respectively toward nodes 208-1-1 and 208-2-2.

However, the alignment shown in FIG. 2C can be different from the alignment shown in FIG. 2B in terms of the distance (when measured from the top view as shown in FIGS. 2B and 2C, respectively) between two signal lines 206-1 and 206-2 within the spiral pattern. For example, the distance (shown as 223 in FIG. 2C) between two signal lines 206-1 and 206-2 within the spiral line shown in FIG. 2C can be greater (e.g., longer) than the distance (shown as 222 in FIG. 2B) between two signal lines 206-1 and 206-2 within the spiral line shown in FIG. 2B. This greater distance between the two signal lines 206-1 and 206-2 may induce a relatively reduced capacitance between the two signal lines 206-1 and 206-2 shown in FIG. 2C than the capacitance between the two signal lines 206-1 and 206-2.

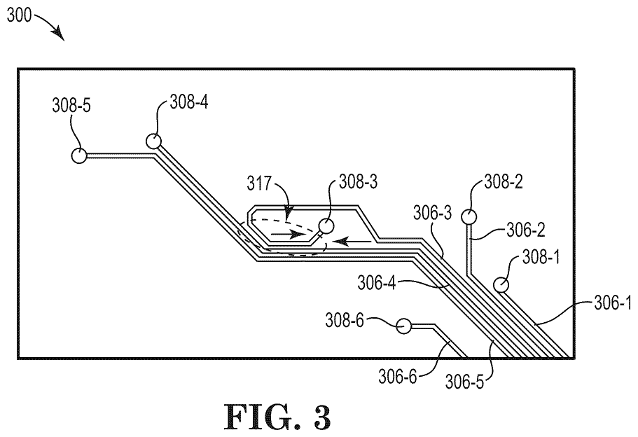

FIG. 3 illustrates a top view of example alignment of signal lines (e.g., signal lines 306-1, 306-2, 306-3, 306-4, 306-5, 306-6) positioned adjacent to one another in accordance with some embodiments of the present disclosure. The signal lines 306-1, 306-2, 306-3, 306-4, 306-5, 306-6 (alternatively referred to as signal lines 306) can be analogous to the signal lines 106 illustrated in FIG. 1. As illustrated in FIG. 3, the signal lines 306-1, 306-2, 306-3, 306-4, 306-5, and 306-6 are coupled to nodes 308-1, 308-2, 308-3, 308-4, 308-5, and 308-6, respectively.

Although embodiments are not so limited, the top view illustrated in FIG. 3 can be a portion of the electronic system 300 (analogous to the electronic system 100) that can correspond to a portion of the controller package (e.g., multi-layer ASIC package). More particularly, the signal lines can be coupled to those nodes (not shown in FIG. 3) of one layer (e.g., top layer) of the multi-layer controller and used for carrying signals of Open NAND Flash Interface (ONFI) communication, for example.

As described herein, the top view illustrated in FIG. 3 can correspond to a plane (e.g., imaginary plane) onto which signal lines 306, nodes 308, are projected. For example, while those signal lines 306 and nodes 308 may not be precisely located on the plane shown FIG. 3, FIG. 3 can illustrate the points, lines, and/or patterns on the plane that are resulting from the projection of the signal lines 306 and nodes 308 onto the plane. Although embodiments are not so limited, the plane (e.g., imaginary plane) may be in parallel with a particular memory component on which signal lines 306 and node 308 are arranged/formed on. For example, the plane may be in parallel with a printed circuit board, a top surface of the controller and/or memory medium/module located on (and in parallel with) the printed circuit board, etc.

Further, signal lines 306-1, . . . , 306-6 are formed (e.g., in an intertwined manner) along substantially the same planes (e.g., a two-dimensional surface as mentioned above, such as height or over the z-axis). Alternatively speaking, the signal lines 306-1, . . . , 306-6 are substantially adjacent to one another on the respective planes (e.g., height or z-axis). For example, a portion of signal line 306-3 near (or adjacent to) the region 317 is on substantially the same plane (e.g., height) as a portion of signal line 306-4 that is near (or adjacent to) the region.

As further illustrated in FIG. 3, the signal line 308-3 is aligned in a (e.g., partial) spiral pattern (e.g., at least partially) in a region indicated by 317. As used herein, the term “partial spiral pattern” refers to a pattern that features incomplete or irregularly shaped elements that still diminish or change in size as they progress/spiral around a central potin or axis. Consider an example, in which signals on signal lines 306-1, 306-2, 306-3, 306-4, 306-5, and 306-6 are respectively transmitted in respective directions towards those nodes 308-1, 308-2, 308-3, 308-4, 308-5, and 308-6 shown in FIG. 3. In this example, the spiral pattern formed by the signal lines 308-3 in the region 317 results in two signals respectively on the signal lines 306-3 and 306-4 being in opposite directions (also as indicated by arrows shown in FIG. 3) at least in the region 317. This intentionally creates inverted inductive coupling, which can cancel and/or mitigate the adverse effects of the crosstalk on the signal lines 306 that would have been caused by dominant inductive coupling along the signal lines 306 prior to the region 317.

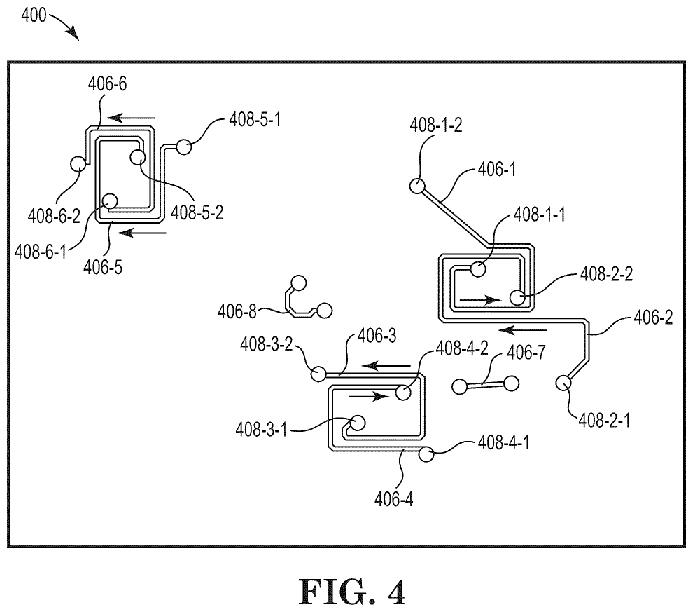

FIG. 4 illustrates a top view of another example alignment of signal lines (e.g., signal lines 406-1, 406-2, 406-3, 406-4, 406-5, 406-6, 406-7, 406-8) positioned adjacent to one another in accordance with some embodiments of the present disclosure. The signal lines 406-1, 406-2, 406-3, 406-4, 406-5, 406-6, 406-7, 406-8 (alternatively referred to as signal lines 406) can be analogous to the signal lines 106 illustrated in FIG. 1.

Although embodiments are not so limited, the top view illustrated in FIG. 4 can be a portion of the electronic system 400 (analogous to the electronic system 100) that can correspond to a portion of the controller package (e.g., multi-layer ASIC package). More particularly, the signal lines can respectively be analogous to 8 input/output (DQ) data bus on one layer (e.g., bottom layer) of the multi-layer controller and used for carrying signals of a particular communication protocol (e.g., double data rate (DDR), such as low-power DDR (LPDDR)).

As described herein, the top view illustrated in FIG. 4 can correspond to a plane (e.g., imaginary plane) onto which signal lines 406, nodes 408, are projected. For example, while those signal lines 406 and nodes 408 may not be precisely located on the plane shown FIG. 4, FIG. 4 can illustrate the points, lines, and/or patterns on the plane that are resulting from the projection of the signal lines 406 and nodes 408 onto the plane. Although embodiments are not so limited, the plane (e.g., imaginary plane) may be in parallel with a particular memory component on which signal lines 406 and node 408 are arranged/formed on. For example, the plane may be in parallel with a printed circuit board, a top surface of the controller and/or memory medium/module located on (and in parallel with) the printed circuit board, etc.

In a number of embodiments, each pair of signal lines 406 (e.g., a pair of signal lines 406-1 and 406-2, a pair of signal lines 406-3 and 406-4, and/or a pair of signal lines 406-5 and 406-6) are formed in an intertwined manner along substantially the same planes (e.g., a two-dimensional surface as mentioned above, such as height or over the z-axis). Alternatively speaking, the signal lines 406-1 and 406-2 are substantially adjacent to one another on the respective planes (e.g., height or z-axis). For example, a portion of signal line 406-2 near (or adjacent to) node 408-1-1 is on substantially the same plane (e.g., height) as a portion of signal line 406-1 that is near (or adjacent to) node 408-2-2. Similarly, those portions of signal lines 406-1 and 406-2 are formed substantially on the same plane as they extend respectively toward nodes 408-1-2 and 408-2-1.

As illustrated in FIG. 4, the signal line 406-1 is coupled between nodes 408-1-1 and 408-1-2; the signal line 406-2 is coupled between nodes 408-2-1 and 408-2-2; the signal line 406-3 is coupled between nodes 408-3-1 and 408-3-2; the signal line 406-4 is coupled between nodes 408-4-1 and 408-4-2; the signal line 406-5 is coupled between nodes 408-5-1 and 408-5-2; the signal line 406-6 is coupled between nodes 408-6-1 and 408-6-2; and the signal line 406-7 is coupled between nodes 408-7-1 and 408-7-2.

Spiral patterns respectively formed by at least some signal lines 406 are intertwined to one another. For example, as illustrated in FIG. 4, a spiral pattern formed by the signal line 406-1 is intertwined with a spiral pattern formed by the signal line 406-2; a spiral pattern formed by the signal line 406-3 is intertwined with a spiral pattern formed by the signal line 406-4; and a spiral pattern formed by the signal line 406-5 is intertwined with a spiral pattern formed by the signal line 406-6.

Assuming that signal lines 406 are “unidirectional” signal lines, the signal lines 406 are aligned to form respective spiral patterns in a manner that signals on two signal lines that respectively form intertwined spiral patterns are transmitted in opposite directions. For example, a node 408-1-1 that is a source of the signal transmitted on the signal line 406-1 is located in an inner portion of the respective spiral pattern, while a node 408-2-1 that is a source of the signal transmitted on the signal line 406-2 is located in an outer portion of the respective spiral pattern intertwined with the spiral pattern formed by the signal line 406-1. This results in two signals to be transmitted on the signal lines 406-1 and 406-2 in opposite directions respectively. For example, the signal is transmitted in a counter-clockwise direction on the signal line 406-1, while the signal is transmitted (e.g., at least partially) in a clockwise direction on the signal line 406-2.

Similarly, a node 408-3-1 that is a source of the signal transmitted on the signal line 406-3 is located in an inner portion of the respective spiral pattern, while a node 408-4-1 that is a source of the signal transmitted on the signal line 406-4 is located in an outer portion of the respective spiral pattern intertwined with the spiral pattern formed by the signal line 406-3. For example, the signal is transmitted in a counter-clockwise direction on the signal line 406-3, while the signal is transmitted (e.g., at least partially) in a clockwise direction on the signal line 406-4. Similarly, a node 408-5-1 that is a source of the signal transmitted on the signal line 406-5 is located in a outer portion of the respective spiral pattern, while a node 408-6-1 that is a source of the signal transmitted on the signal line 406-6 is located in an inner portion of the respective spiral pattern intertwined with the spiral pattern formed by the signal line 406-5. For example, the signal is transmitted in a clockwise direction on the signal line 406-5, while the signal is transmitted (e.g., at least partially) in a counter-clockwise direction on the signal line 406-6.

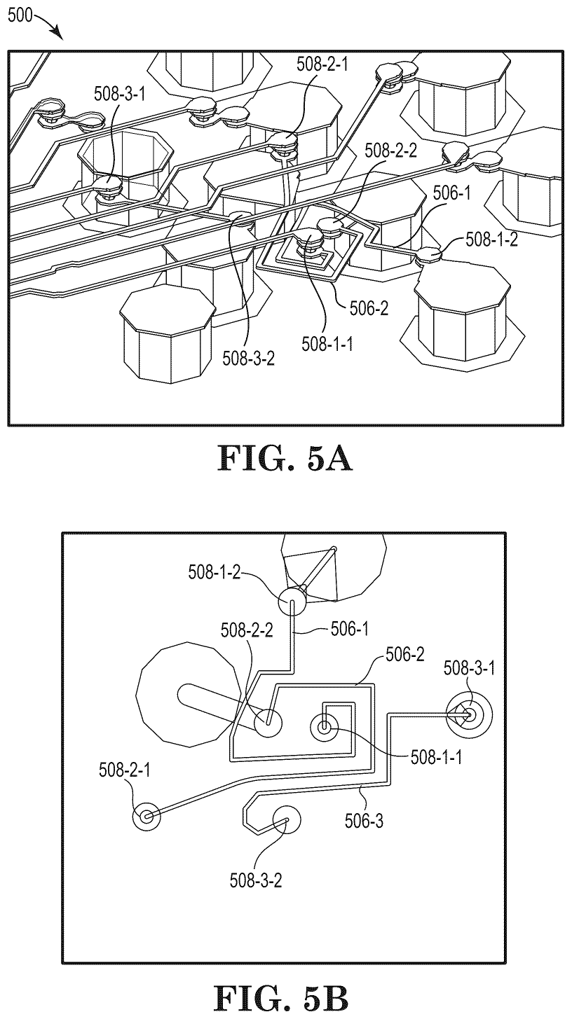

FIGS. 5A and 5B respectively illustrate three-dimensional and top views of example alignment of signal lines positioned adjacent to one another in accordance with some embodiments of the present disclosure. The signal lines 506-1, 506-2, 506-3 (alternatively referred to as signal lines 506) can be analogous to the signal lines 106 illustrated in FIG. 1.

Although embodiments are not so limited, the view illustrated in FIGS. 5A-5B can be a portion of the electronic system 500 (analogous to the electronic system 100) that can correspond to a portion of the memory package (e.g., NAND). As shown in FIGS. 5A-5B, nodes 508-1-1, 508-2-1, 508-3-1 can serve as intermediate nodes respectively for signal lines 506-1, 506-2, 506-3.

As described herein, the top view illustrated in FIG. 5B can correspond to a plane (e.g., imaginary plane) onto which signal lines 506, nodes 508, are projected. For example, while those signal lines 506 and nodes 508 may not be precisely located on the plane shown FIG. 5B,

FIG. 5B can illustrate the points, lines, and/or patterns on the plane that are resulting from the projection of the signal lines 506 and nodes 508 onto the plane. Although embodiments are not so limited, the plane (e.g., imaginary plane) may be in parallel with a particular memory component on which signal lines 506 and node 508 are arranged/formed on. For example, the plane may be in parallel with a printed circuit board, a top surface of the controller and/or memory medium/module located on (and in parallel with) the printed circuit board, etc.

In a number of embodiments, signal lines 506-1, 506-2, and/or 506-3 are formed in an intertwined manner along substantially the same planes (e.g., a two-dimensional surface as mentioned above, such as height or over the z-axis), as also illustrated in FIG. 5A. Alternatively speaking, the signal lines 506-1 and 506-2 are substantially adjacent to one another on the respective planes (e.g., height or z-axis). For example, a portion of signal line 506-2 near (or adjacent to) node 508-2-2 is on substantially the same plane (e.g., height) as a portion of signal line 506-1 that is near (or adjacent to) node 508-1-1. Similarly, those portions of signal lines 506-1 and 506-2 are formed substantially on the same plane as they extend respectively toward nodes 508-1-2 and 508-2-1.

As illustrated in FIGS. 5A and 5B, at least three signal lines 506-1, 506-2, and 506-3 are aligned in a manner that forms respective/various spiral patterns. While the spiral patterns formed by the signal lines 506-1 and 506-2 are intertwined to one another, the spiral pattern formed by the signal line 506-3 is not intertwined with the other spiral patterns shown in FIG. 5B.

Considering that the portion of the electronic system 500 corresponds to a memory package, such as a NAND package, spiral patterns can be formed (by respective signal lines) in various locations of the electronic system 500, such as in a controller package (e.g., ASIC package). For example, the spiral patterns can be formed on the memory package only, or the controller package only, or on both. While additional spiral patterns in different areas of the electronic system 500, such as in both the controller and memory packages, may further improve crosstalk cancellation, the decision on the number and placement of these spiral patterns can involve balancing the benefits with the costs (e.g., implementation costs) to optimize/maximize the benefits.

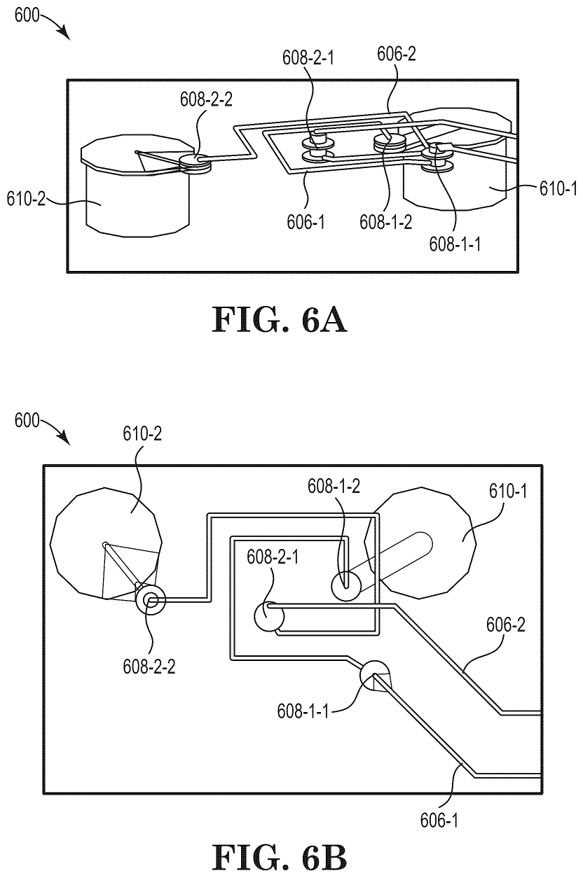

FIGS. 6A and 6B illustrate three-dimensional and top views of example alignment of signal lines positioned adjacent to one another in accordance with some embodiments of the present disclosure. The signal lines 606-1 and 606-2 (alternatively referred to as signal lines 606) can be analogous to the signal lines 106 illustrated in FIG. 1.

Although embodiments are not so limited, the view illustrated in FIGS. 6A-6B can be a portion of the electronic system 600 (analogous to the electronic system 100) that can correspond to a portion of the memory package (e.g., NAND). As shown in FIGS. 6A-6B, nodes 608-1-1, 608-2-1, 608-3-1 can serve as intermediate nodes respectively for signal lines 606-1, 606-2, 606-3.

The components 610 may be analogous to the components 102, 104 illustrated in FIG. 1. Although embodiments are not so limited, the components 610-1 and 610-2 can respectively be vias, BGA balls, etc. of the electronic system 600, which can be a controller package (e.g., 6-layer ASIC package) and/or a memory package (e.g., NAND package).

As described herein, the top view illustrated in FIG. 5B can correspond to a plane (e.g., imaginary plane) onto which signal lines 606, nodes 608, are projected. For example, while those signal lines 606 and nodes 608 may not be precisely located on the plane shown FIG. 5B, FIG. 5B can illustrate the points, lines, and/or patterns on the plane that are resulting from the projection of the signal lines 606 and nodes 608 onto the plane. Although embodiments are not so limited, the plane (e.g., imaginary plane) may be in parallel with a particular memory component on which signal lines 606 and node 608 are arranged/formed on. For example, the plane may be in parallel with a printed circuit board, a top surface of the controller and/or memory medium/module located on (and in parallel with) the printed circuit board, etc.

In a number of embodiments, signal lines 606-1 and 606-2 are formed in an intertwined manner along substantially the same planes (e.g., a two-dimensional surface as mentioned above, such as height or over the z-axis), as also illustrated in FIG. 5A. Alternatively speaking, the signal lines 606-1 and 606-2 are substantially adjacent to one another on the respective planes (e.g., height or z-axis). For example, a portion of signal line 606-2 near (or adjacent to) node 608-2-1 is on substantially the same plane (e.g., height) as a portion of signal line 606-1 that is near (or adjacent to) node 608-1-2. Similarly, those portions of signal lines 606-1 and 606-2 are formed substantially on the same plane as they extend respectively toward nodes 608-1-1 and 608-2-2.

Similar to FIGS. 2A-2C and 3-5, the signal lines are aligned to form respective spiral patterns. Further, the spiral patterns respectively formed by the signal lines 606-1 and 606-2 are intertwined to one another. Alternatively speaking, a line on the plane (corresponding to the top view of FIG. 6B) between two nodes (608-1-1 and 608-1-2 or 608-2-1 and 608-2-2) of one signal line (606-1 or 606-2) intersects the other signal line.

The node 608-2-1 that serves as an intermediate node is implemented to change the direction of the signal transmitted on the signal line 606-2 in relation to a direction of a signal transmitted on the signal line 606-1. For example, consider an example, in which signals are transmitted respectively on the signal lines 606-1 and 606-2 and respectively toward the components 610-1 and 610-2 (e.g., in a direction from the node 608-1-1 or 608-2-1 to the node 608-1-2 or 608-2-2). While the signal transmitted on the signal line 606-1 is transmitted in a counter-clockwise direction on the spiral pattern formed by the signal line 606-1, the signal transmitted on the signal line 606-2 that has been transmitted in a similar direction as the signal on the signal line 606-1 is transmitted in a clockwise direction on the spiral pattern formed by the signal line 606-2 due to the intermediate node 608-2-1. This result in signals to be transmitted in opposite directions on those adjacent portions of the signal lines 606-1, 606-2.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system, comprising:
a first signal line coupled between a first node and a second node respectively on one or more planes; and
a second signal line arranged adjacent to the first signal line and coupled between a third node and a fourth node respectively on one or more planes, wherein the first signal line is aligned in a first spiral pattern that is arranged adjacent to the first spiral pattern.

2. The system of claim 1, wherein the first node corresponds to an inner node of the first spiral pattern, while the second node corresponds to an outer node of the first spiral pattern.

3. The system of claim 2, wherein:
the second signal line is also aligned in a second spiral pattern that is intertwined with the first spiral pattern; and
the third node corresponds to an inner node of the second spiral pattern, while the fourth node corresponds to an outer node of the second spiral pattern.

4. The system of claim 3, wherein:
the first and fourth nodes respectively correspond to a source node; and
the second and third nodes respectively correspond to a destination node.

5. The system of claim 3, further comprising:
a third signal line aligned in a third spiral pattern;
a fourth signal line aligned in a fourth spiral pattern that is intertwined with the third spiral pattern.

6. The system of claim 5, wherein:
a first distance between the first signal line and the second signal line respectively within the first spiral pattern or the second spiral pattern is substantially constant; and
a second distance between the third signal line and the fourth signal line respectively within the third spiral pattern or the fourth spiral pattern is substantially constant.

7. The system of claim 6, wherein:
the second distance is shorter than the first distance to achieve a relatively reduced mutual capacitance between the third and fourth signal lines than a mutual capacitance between the first and the second signal lines.

8. The system of claim 5, wherein:
the first spiral pattern, the second spiral pattern, or both, includes a series of a first quantity of shapes that spiral around a first central point in a progressively diminishing manner; and
the third spiral pattern, the fourth spiral pattern, or both, includes a series of a second quantity of shapes that spiral around a second central point in a progressively diminishing manner.

9. The system of claim 8, wherein the first quantity of shapes is of a greater quantity than the second quantity of shapes to achieve a relatively increased mutual inductance between the first and the second signal lines than a mutual capacitance between the third and the fourth signal lines.

10. A system, comprising:
a first spiral pattern formed on a particular plane by a first signal line that is coupled between a first inner node and a first outer node of the first spiral pattern; and
a second spiral pattern intertwined with the first spiral pattern and formed on the particular plane by a second signal line that is coupled between a second inner node and a second outer node of the second spiral pattern;
wherein the first inner node corresponds to a source node and the first outer node corresponds to a destination node such that a signal is transmitted on the first signal line in a direction from the first inner node to the first outer node;
wherein the second outer node corresponds to a source node and the second inner node corresponds to a destination node such that a signal is transmitted on the second signal line in a direction from the second outer node to the second inner node.

11. The system of claim 10, wherein:
the first spiral pattern includes a series of a first quantity of shapes that spiral around a first central point in a progressively diminishing manner, wherein the first inner node is located substantially on the first central point; and
the second spiral pattern includes a series of a second quantity of shapes that spiral around a second central point in a progressively diminishing manner, wherein the second inner node is located substantially on the second central point.

12. The system of claim 11, wherein:
the first outer node is located external to the first quantity of shapes; and
the second outer node is located external to the second quantity of shapes.

13. An apparatus, comprising:
a first component; and
a first signal line coupled between a first node of the first component and a second node, wherein the first signal line adjacent to one or more other signal lines of the first component is aligned, on the first component, in a first spiral pattern including a series of a quantity of shapes that spiral around a central point in a progressively diminishing manner.

14. The apparatus of claim 13, wherein the second node is an intermediate node that is part of the first signal line and is not part of the first component.

15. The apparatus of claim 13, wherein the first node is a destination node of a signal transmitted on the first signal line.

16. The apparatus of claim 13, wherein the second node is part of a second component.

17. The apparatus of claim 16, wherein:
the apparatus corresponds to a multi-layer controller;
the first component corresponds to a via of a first layer; and
the second component corresponds to a via of a second layer or a ball grid array (BGA) ball coupled between the second layer of the controller and a printed circuit board (PCB).

18. The apparatus of claim 16, wherein:
the first component, the second component, or both, corresponds to a memory package, a controller package, or any combination thereof.

19. The apparatus of claim 16, further comprising:
a second signal line coupled between a third node of the second component and a fourth node, wherein the second signal line is aligned in a second spiral pattern including a series of a quantity of shapes that spiral around a central point in a progressively diminishing manner.

20. The apparatus of claim 19, wherein the second spiral pattern is intertwined with the first spiral pattern such that:
a first line on a particular plane intersects a pattern on the particular plane resulting from projecting the second spiral pattern onto the particular plane, wherein the first line is between two points on the particular plane obtained by projecting the first node and the second node onto the particular plane; and
a second line on the particular plane intersects a pattern on the particular plane resulting from projecting the first spiral pattern onto the particular plane, wherein the second line is between two points on the particular plane obtained by projecting the third node and the fourth node onto the particular plane.
